(19) United States
(12) Patent Application Publication
(10) Pub. No.: US 2024/0186047 A1
(43) Pub. Date: Jun. 6, 2024

(54) Current-Perpendicular-to-Plane Giant Magneto-Resistive Element and Manufacturing Method Thereof

(71) Applicant: NATIONAL INSTITUTE FOR MATERIALS SCIENCE, Tsukuba-shi, Ibaraki (JP)

(72) Inventors: Yuichi FUJITA, Tsukuba (JP); Yuya SAKURABA, Tsukuba (JP); Yoshio MIURA, Tsukuba (JP); Taisuke SASAKI, Tsukuba (JP); Kazuhiro HONO, Tsukuba (JP)

(73) Assignee: NATIONAL INSTITUTE FOR MATERIALS SCIENCE, Tsukuba-shi, Ibaraki (JP)

(21) Appl. No.: 18/284,964

(22) PCT Filed: Mar. 1, 2022
(86) PCT No.: PCT/JP2022/008645

§ 371 Date: Sep. 29, 2023

(30) Foreign Application Priority Data
Mar. 31, 2021 (JP) 2021-061205

(51) Int. Cl. H01F 10/32; G11B 5/39

(52) U.S. Cl. CPC H01F 10/3254; G11B 5/39; G11B 2005/3996

(57) ABSTRACT

The present invention provides a current-perpendicular-to-plane giant magneto-resistive element that can use a high spin polarization (β) and spin asymmetry (γ) at the interface between layers, and that has a multilayered structure for easy film thickness design.

Used is a current-perpendicular-to-plane giant magneto-resistive element comprising: a substrate (11) made of an MgO substrate; and a giant magneto-resistive effect layer (17) that has at least one multilayer having first non-magnetic layers (13a), (13b), a lower ferromagnetic layer (14a), a lower Heusler alloy layer (14b), a second non-magnetic layer (15), an upper Heusler alloy layer (16b), and an upper ferromagnetic layer (16a) formed on the substrate (11).

### TECHNICAL FIELD

The present invention relates to a current-perpendicular-to-plane giant magneto-resistive element and a method for manufacturing the current-perpendicular-to-plane giant magneto-resistive element.

### BACKGROUND ART

Current-perpendicular-to-plane giant magnetoresistance (CPP-GMR) elements have attracted attention as a technique of enhancing performance of a magnetic device such as a magnetic head of a hard disk drive, a magnetic sensor, or a spin torque oscillator. A basic CPP-GMR element has a structure of a ferromagnetic (FM) layer/a non-magnetic (NM) layer/a ferromagnetic (FM) layer, and this multilayered thin film is processed into a pillar shape having a size of several submicrons or less to produce a CPP-GMR element.

In operation of a current-perpendicular-to-plane giant magneto-resistive element, a current is applied to the pillar in the direction perpendicular to an interface in the multilayered structure, and change in the electric resistance of the multilayered structure between the time when the magnetization directions of the two ferromagnetic layers are relatively parallel and the time when the magnetization directions are relatively antiparallel is used.

For improvement in performance of a CPP-GMR element, technological development is required for improving the magnetoresistance (MR) ratio and the resistance change×pillar area product (ARA), which are performance indexes. In the case of using CoFe, which is a conventional material, as a material of a ferromagnetic layer, there has been a problem that the MR ratio is only about 3% [Non-Patent Literature 1] and is insufficient to mount the material on an actual magnetic device.

For improvement in MR ratio and ΔRA, it is important to select a material system in which the spin polarization (β) is high in the bulk of a ferromagnetic layer and the spin asymmetry (γ) is high at an interface between layers. So far, a Heusler alloy/Ag (or AgZn)/Heusler alloy epitaxial CPP-GMR element with (001) orientation has been developed in which a Co-based Heusler alloy having a high β (such as Co₂(Fe_{0.4}Mn_{0.6})Si or Co₂Fe(Ga_{0.5}Ge_{0.5})) is applied to a ferromagnetic layer, and Ag or AgZn having good lattice matching is used as a spacer material in a non-magnetic layer, resulting in realization of an MR ratio of 30-60% and ΔRA=8-20 mΩμm² [Patent Literature 1-2, Non-Patent Literature 2-4].

Furthermore, a very high MR ratio (82%) and a very high ΔRA (31 mΩμm²) have been recently achieved in a CPP-GMR element having a Heusler alloy/NiAl/Ag/NiAl/Heusler alloy epitaxial structure in which an ultrathin (0.21 nm) NiAl layer is inserted at a Heusler alloy/Ag interface [Patent Literature 3]. In this element, the high γ at the Heusler alloy/NiAl interface is used, but there is a problem that element performance varies due to the problem about homogeneity of the 0.21 nm ultrathin insertion layer.

Meanwhile, among more practical polycrystalline magneto-resistive elements, MR ratios of 18% and 54% are observed in CPP-GMR elements using a Heusler alloy Co₂Mn_{0.6}Fe_{0.4}Ge and an AgSn spacer and using a Heusler alloy Co₂Mn_{0.6}Fe_{0.4}Ge and an AgInZnO precursor spacer, respectively [Patent Literature 4]. However, the large MR ratio of the latter is due to the current confinement structure spacer, and in this case, there is also a problem that element performance varies. Considering these results, a novel idea is required for stable realization of a large MR ratio and a large ARA with little variation in elements in both single-crystal and polycrystalline devices.

### CITATION LIST

### Patent Literature

PATENT LITERATURE 1: JP 2017-103419 A
PATENT LITERATURE 2: WO 2017/017978 A1
PATENT LITERATURE 3: JP 2017-097935 A
PATENT LITERATURE 4: WO 2019/193871 A1

### NON-PATENT LITERATURE

NON-PATENT LITERATURE 1: S. Yuasa et al., J. Appl. Phys. 92, 2646 (2002)
NON-PATENT LITERATURE 2: Y. Sakuraba et al., Appl. Phys. Lett. 101, 252408 (2012)
NON-PATENT LITERATURE 3: S. Li et al., Appl. Phys. Lett. 103, 042405 (2013)
NON-PATENT LITERATURE 4: Y. Du et al., Appl. Phys. Lett. 107, 112405 (2015)
NON-PATENT LITERATURE 5: J. W. Jung et al., Appl. Phys. Lett. 108, 102408 (2016)

### SUMMARY OF INVENTION

### Technical Problem

So far, the spin asymmetry (γ) at a ferromagnetic layer/non-magnetic layer interface has been verified in various combinations, and as described above, there is a report on improvement in performance of a CPP-GMR element by forming a Heusler alloy/NiAl/Ag/NiAl/Heusler alloy epitaxial structure and using the high spin asymmetry (γ) of the Heusler alloy/NiAl [Non-Patent Literature 5].

However, in this structure, thickness control of the NiAl insertion layer in the order of sub-nanometers is required, and there is also a problem that the yield of the product is affected.

Therefore, it is desired to explore a current-perpendicular-to-plane giant magneto-resistive element having a multilayered structure in which a high spin polarization (β) and high spin asymmetry (γ) at an interface between layers can be used and film thickness design is easy.

### Solution to Problem

As a result of intensive studies to solve the above problems, the present inventors have conceived that performance of a CPP-GMR element can be improved by using a multilayered structure film using a high spin polarization (β) of a Heusler alloy and spin asymmetry (γ) at an interface between a ferromagnetic layer and a Heusler alloy layer, and have completed the present invention.

[1] A current-perpendicular-to-plane giant magneto-resistive element of the present invention comprises a substrate 11 composed of a silicon substrate, a base layer layered on the substrate 11, first non-magnetic layers 13a and 13b layered on the base layer, and a giant magneto-resistive effect layer 17 including at least one multilayer including a lower ferromagnetic layer 14a, a lower Heusler alloy layer 14b, a second non-magnetic layer 15, an upper Heusler alloy layer 16b, and an upper ferromagnetic layer 16a.

[2] In the current-perpendicular-to-plane giant magneto-resistive element [1] of the present invention, the silicon substrate is preferably a Si(001) single-crystal substrate.

[3] In the current-perpendicular-to-plane giant magneto-resistive element [1] or [2] of the present invention, the base layer is preferably composed of at least one selected from the group consisting of Cr, Fe, and CoFe.

[4] In any one of the current-perpendicular-to-plane giant magneto-resistive elements [1] to [3] of the present invention, the base layer preferably has a thickness of 10 nm or more and less than 200 nm.

[5] A current-perpendicular-to-plane giant magneto-resistive element of the present invention comprises, for example as shown in FIG. 1, a substrate 11 composed of a MgO substrate, first non-magnetic layers 13a and 13b layered on the substrate 11, and a giant magneto-resistive effect layer 17 including at least one multilayer including a lower ferromagnetic layer 14a, a lower Heusler alloy layer 14b, a second non-magnetic layer 15, an upper Heusler alloy layer 16b, and an upper ferromagnetic layer 16a.

[6] In the current-perpendicular-to-plane giant magneto-resistive element [5] of the present invention, the MgO substrate is preferably a (001) single-crystal substrate.

[7] In any one of the current-perpendicular-to-plane giant magneto-resistive elements [1] to [6] of the present invention,
the first non-magnetic layers 13a and 13b are preferably at least one selected from the group consisting of Ag, V, Cr, W, Mo, Au, Pt, Pd, Ta, Ru, Re, Rh, NiO, CoO, TiN, and CuN,
the lower ferromagnetic layer is preferably composed of Fe, Co, Ni, or a binary or ternary alloy of Fe, Co, and Ni,
the lower Heusler alloy layer is preferably a Co-based Heusler alloy,
the second non-magnetic layer is preferably composed of at least one selected from the group consisting of Ag, Cu, Al, AgZn, and AgSn,
the upper Heusler alloy layer is preferably a Co-based Heusler alloy, and
the upper ferromagnetic layer is preferably composed of Fe, Co, Ni, or a binary or ternary alloy of Fe, Co, and Ni.

[8] In the current-perpendicular-to-plane giant magneto-resistive element [7] of the present invention, the Co-based Heusler alloy preferably has a formula of CO₂YZ wherein
Y is composed of at least one selected from the group consisting of Ti, V, Cr, Mn, and Fe and Z is composed of at least one selected from the group consisting of Al, Si, Ga, Ge, In, and Sn.

[9] In any one of the current-perpendicular-to-plane giant magneto-resistive elements [1] to [8] of the present invention,
the first non-magnetic layers 13a and 13b preferably each have a thickness of 0.5 nm or more and less than 100 nm,
the lower ferromagnetic layer preferably has a thickness of 0.2 nm or more and less than 7 nm,
the lower Heusler alloy layer preferably has a thickness of 1.0 nm or more and less than 7 nm,
the second non-magnetic layer preferably has a thickness of 1 nm or more and less than 20 nm,
the upper Heusler alloy layer preferably has a thickness of 1.0 nm or more and less than 7 nm,
the upper ferromagnetic layer preferably has a thickness of 0.2 nm or more and less than 7 nm,
a total thickness of the lower ferromagnetic layer and the lower Heusler alloy layer is preferably 1.2 nm or more and less than 14 nm, and
a total thickness of the upper ferromagnetic layer and the upper Heusler alloy layer is preferably 1.2 nm or more and less than 14 nm.

[10] Any one of the current-perpendicular-to-plane giant magneto-resistive elements [1] to [9] of the present invention preferably has a magnetoresistance ratio of 20% or more and a resistance change-area product (ARA) of 7 mΩμm² or more.

[11] In any one of the current-perpendicular-to-plane giant magneto-resistive elements [1] to [10] of the present invention, the giant magneto-resistive effect layer preferably has a single-crystal structure having an epitaxial crystal orientation of a (001), (110), or (211) orientation as a crystal orientation indicated by a Miller index.

[12] In any one of the current-perpendicular-to-plane giant magneto-resistive elements [1] to [10] of the present invention, the giant magneto-resistive effect layer preferably has a polycrystalline structure.

[13] A device of the present invention comprises any one of the current-perpendicular-to-plane giant magneto-resistive elements [1] to [12]. [14] The device of the present invention is preferably a readout head to be used in a storage element, a magnetic field sensor, a spin electronic circuit, or a tunnel magnetoresistance (TMR) device.

[15] A method for manufacturing a current-perpendicular-to-plane single-crystal giant magneto-resistive element of the present invention can comprise
a step of preparing a silicon substrate,
a step of forming a base layer having a single-crystal structure on the silicon substrate,
a step of forming a film of a first non-ferromagnetic material at a substrate temperature of 0° C. or more and 1000° C. or less on the base layer formed on the silicon substrate,
a step of forming, on the film of the first non-ferromagnetic material formed on the base layer, a giant magneto-resistive effect layer including at least one multilayer including a lower ferromagnetic material layer, a lower Heusler alloy layer, a second non-ferromagnetic material layer, an upper Heusler alloy layer, and an upper ferromagnetic material layer, and
a step of heat-treating the silicon substrate, with the giant magneto-resistive effect layer formed, at 0° C. or more and 1000° C. or less.

[16] A method for manufacturing a current-perpendicular-to-plane single-crystal giant magneto-resistive element of the present invention can comprise
a step of preparing a MgO substrate,
a step of forming a film of a first non-ferromagnetic material at a substrate temperature of 0° C. or more and 1000° C. or less on the MgO substrate,
a step of forming, on the film of the first non-ferromagnetic material formed on the MgO substrate, a giant magneto-resistive effect layer including at least one multilayer including a lower ferromagnetic material layer, a lower Heusler alloy layer, a second non-ferromagnetic material layer, an upper Heusler alloy layer, and an upper ferromagnetic material layer, and
a step of heat-treating the MgO substrate, with the giant magneto-resistive effect layer formed, at 0° C. or more and 1000° C. or less.

[17] A method for manufacturing a current-perpendicular-to-plane polycrystalline giant magneto-resistive element of the present invention can comprise
a step of preparing a substrate of silicon, glass, alumina, germanium, gallium arsenide, yttria-stabilized zirconia, or AlTiC,
a step of forming a base layer that serves as a polycrystalline electrode on the substrate,
a step of forming a film of a first non-ferromagnetic material on the base layer formed on the substrate,
a step of forming, on the film of the first non-ferromagnetic material formed on the base layer, a giant magneto-resistive effect layer including at least one multilayer including a lower ferromagnetic material layer, a lower Heusler alloy layer, a second non-ferromagnetic material layer, an upper Heusler alloy layer, and an upper ferromagnetic material layer, and
a step of heat-treating the substrate, with the giant magneto-resistive effect layer formed, at 0° C. or more and 500° C. or less.

### Advantageous Effects of Invention

According to the current-perpendicular-to-plane giant magneto-resistive element of the present invention, the MR ratio and ARA of the CPP-GMR element can be improved due to the high spin polarization (β) of the Heusler alloy layer and the high spin asymmetry (γ) at the interface between the ferromagnetic layer and the Heusler alloy layer in the ferromagnetic/Heusler alloy/non-magnetic/Heusler alloy/ferromagnetic multilayered structure.

### BRIEF DESCRIPTION OF DRAWINGS

FIG. 1 is a configuration cross-sectional view of a magneto-resistive element including a giant magneto-resistive effect layer and showing a first embodiment of the present invention.

FIG. 2 shows flowcharts illustrating a method for manufacturing a magneto-resistive element 10 including a giant magneto-resistive effect layer, using a silicon substrate, and showing the first embodiment of the present invention, and (A) is a whole schematic process diagram, and (B) is a detailed diagram of a step of forming a giant magneto-resistive effect layer.

FIG. 3 shows flowcharts illustrating a method for manufacturing a magneto-resistive element including a giant magneto-resistive effect layer, using a MgO substrate, and showing a second embodiment of the present invention, and (A) is a whole schematic process diagram, and (B) is a detailed diagram of a step of forming a giant magneto-resistive effect layer.

FIG. 4 is a view showing a multilayered structure of a current-perpendicular-to-plane giant magneto-resistive element showing an embodiment of the present invention.

FIG. 5 is a view showing a main part of a cross-sectional transmission electron microscope image of a current-perpendicular-to-plane giant magneto-resistive element showing an embodiment of the present invention.

FIG. 6 is a view showing a CPP-GMR element structure that is produced at a low magnification and shows an embodiment of the present invention and showing arrangement for measurement of magnetoresistance.

FIG. 7 is a graph showing an MR-observation curve of a CPP-GMR element structure that is produced at a low magnification and shows an embodiment of the present invention.

FIG. 8 shows characteristics of an embodiment of the present invention, and (A) is a graph showing dependency of MR ratio on film thickness t, and (B) is a graph showing dependency of ARA on film thickness t.

FIG. 9 shows an embodiment of the present invention, and (A) shows calculation results of MR ratio in the cases of a film thickness t of 4 nm and a film thickness t of 7 nm, and (B) shows calculation results of ARA in the cases of a film thickness t of 4 nm and a film thickness t of 7 nm.

### DESCRIPTION OF EMBODIMENTS

Hereinafter, embodiments of the present invention will be described with reference to the drawings.

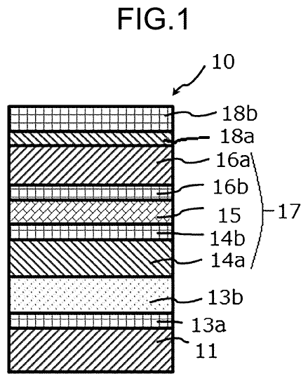

FIG. 1 is a configuration cross-sectional view of a magneto-resistive element including a giant magneto-resistive effect layer and showing a first embodiment of the present invention. In this figure, a magneto-resistive element 10 including a giant magneto-resistive effect layer of the present embodiment includes a substrate 11, first non-magnetic layers 13a and 13b layered on the substrate 11, a giant magneto-resistive effect layer 17, and cap layers 18a and 18b.

The giant magneto-resistive effect layer 17 includes a lower ferromagnetic layer 14a, an upper ferromagnetic layer 16a, and a second non-magnetic layer 15 provided between the lower ferromagnetic layer 14a and the upper ferromagnetic layer 16a. Furthermore, a first Heusler alloy insertion layer (lower Heusler alloy layer) 14b is provided between the lower ferromagnetic layer 14a and the second non-magnetic layer 15, and a second Heusler alloy insertion layer (upper Heusler alloy layer) 16b is provided between the upper ferromagnetic layer 16a and the second non-magnetic layer 15. The total thickness of the lower ferromagnetic layer 14a and the first Heusler alloy insertion layer 14b is selected from a range of 1.2 nm to 14 nm, and the thickness of the first Heusler alloy insertion layer 14b may be adjusted so that the total thickness selected as described above is constant. The total thickness of the upper ferromagnetic layer 16a and the second Heusler alloy insertion layer 16b is selected from a range of 1.2 nm to 14 nm, and the thickness of the second Heusler alloy insertion layer 16b may be adjusted so that the total thickness selected as described above is constant. The first Heusler alloy insertion layer 14b and the second Heusler alloy insertion layer 16b may have the same thickness or different thicknesses.

The substrate 11 is preferably a MgO substrate or a silicon substrate. In a case where the substrate 11 is a silicon substrate, a large size Si substrate such as a general-purpose Si substrate having a size of 8 inches can be used. In a case where the substrate 11 is a silicon substrate, a base layer 12 is preferably provided between the silicon substrate and the first non-magnetic layers 13a and 13b. The base layer 12 is preferably composed of, for example, at least one selected from the group consisting of NiAl, CoAl, and FeAl. In a case where the substrate 11 is a MgO substrate, it is unnecessary to provide the base layer 12, but the base layer 12 may be provided.

The first non-magnetic layers 13a and 13b also serves as lower electrode layers, and are preferably composed of at least one selected from the group consisting of Ag, Cr, Fe, W, Mo, Au, Pt, Pd, Rh, Ta, NiFe, and NiAl. The first non-magnetic layers 13a and 13b may have, but are not limited to, a two-layer structure of a Cr layer also serving as a base layer and an Ag layer also serving as a lower electrode layer as in Examples, or may have a single-layer structure. The first non-magnetic layers 13a and 13b preferably each have a thickness of 0.5 nm or more and less than 100 nm. If the first non-magnetic layers 13a and 13b each have a thickness of less than 100 nm, the surface roughness is less likely to deteriorate, and if the thickness is 0.5 nm or more, a continuous film is formed to obtain an effect as a base layer easily and it is further expected that an MR ratio required for the present use can be obtained.

The lower ferromagnetic layer 14a is preferably composed of at least one selected from Fe and CoFe. The lower ferromagnetic layer 14a preferably has a thickness of 0.2 nm to 7 nm. If the lower ferromagnetic layer 14a has a thickness of less than 10 nm, the influence of spin relaxation in the ferromagnetic layer is small, and if the thickness is 0.2 nm or more, the thickness corresponds to the thickness of one atomic layer (ML) and is preferable in that a continuous film is easily formed. The composition material of the lower ferromagnetic layer 14a does not contain a Heusler alloy.

The first Heusler alloy insertion layer 14b is preferably composed of a Co-based Heusler alloy. The first Heusler alloy insertion layer 14b preferably has a thickness of 1.0 nm or more and less than 7 nm. If the thickness is 1.0 nm or more, the contribution of spin scattering of the bulk of the Heusler alloy insertion layer is less likely to decrease, leading to a further technical advantage in that the MR ratio is less likely to decrease. If the thickness is less than 7 nm, the influence of spin relaxation is less likely to increase, and it is further expected that an MR ratio required for the present use can be obtained.

The Co-based Heusler alloy preferably has a formula of Co₂YZ wherein Y is composed of at least one selected from the group consisting of Ti, V, Cr, Mn, and Fe and Z is composed of at least one selected from the group consisting of Al, Si, Ga, Ge, and Sn.

The second non-magnetic layer 15 is preferably composed of at least one selected from the group consisting of Ag, Cu, Al, and AgZn. The second non-magnetic layer 15 preferably has a thickness of 1 nm or more and less than 20 nm. If the second non-magnetic layer 15 has a thickness of less than 20 nm, the influence of spin relaxation in the non-magnetic layer is less likely to increase, and if the thickness is 1 nm or more, magnetic coupling between the upper ferromagnetic layer 16a and the lower ferromagnetic layer 14a is less likely to be generated, so that the relative magnetization angle is less likely to decrease, and it is further expected that an MR ratio required for the present use can be obtained.

The second Heusler alloy insertion layer 16b is preferably composed of a Co-based Heusler alloy. The second Heusler alloy insertion layer 16b preferably has a thickness of 1.0 nm or more and less than 7 nm. If the thickness is 1.0 nm or more, the contribution of spin scattering of the bulk of the Heusler alloy insertion layer is less likely to decrease, leading to a further technical advantage in that the magnetoresistance ratio is less likely to decrease. If the thickness is less than 7 nm, the influence of spin relaxation is less likely to increase, and it is further expected that an MR ratio required for the present use can be obtained.

The upper ferromagnetic layer 16a is preferably composed of at least one selected from Fe and CoFe. The upper ferromagnetic layer 16a preferably has a thickness of 0.2 nm or more and less than 7 nm. If the upper ferromagnetic layer 16a has a thickness of less than 7 nm, the influence of spin relaxation in the ferromagnetic layer is less likely to increase, and if the thickness is 0.2 nm or more, the thickness corresponds to the thickness of one atomic layer (ML) and therefore a continuous film is easily formed.

The cap layers 18a and 18b are preferably composed of at least one selected from the group consisting of Ag, Cr, W, Mo, Au, Pt, Pd, Ta, Ru, and Rh. The cap layers 18a and 18b preferably have a thickness of 1 nm or more and less than 20 nm. The cap layers 18a and 18b may have, but are not limited to, a two-layer structure of an Ag layer also serving as an upper electrode layer and a Ru layer also serving as a protective layer as in Examples, or may have a single-layer structure.

Next, a process of manufacturing a device configured as described above will be described.

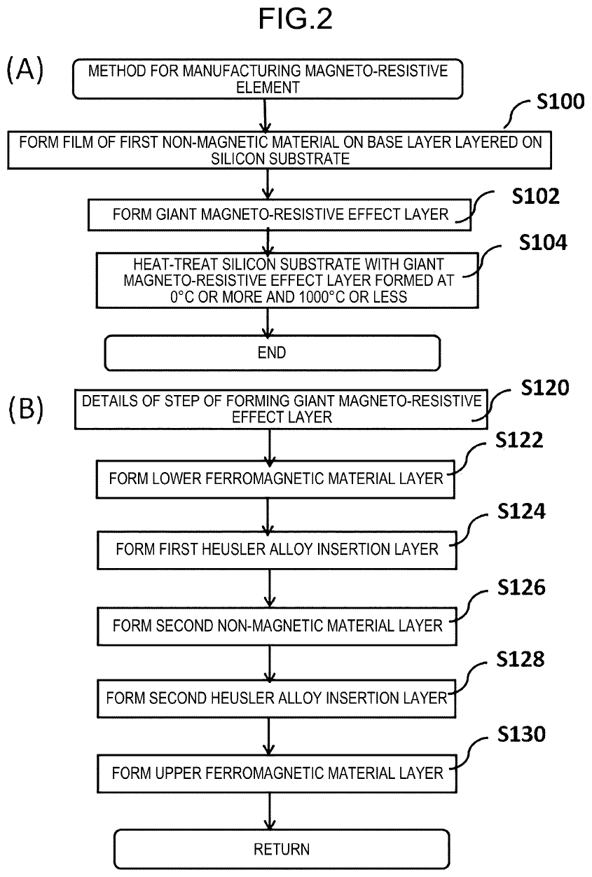

FIG. 2 shows flowcharts illustrating a method for manufacturing a magneto-resistive element 10 including a giant magneto-resistive effect layer, using a silicon substrate, and showing the first embodiment of the present invention, and (A) is a whole schematic process diagram, and (B) is a detailed diagram of a step of forming a giant magneto-resistive effect layer. In FIG. 2(A), a film of a first non-magnetic material is formed at a substrate temperature of 0° C. or more and 1000° C. or less on a silicon substrate 11 (S100). Next, on the film of the first non-magnetic material formed on the silicon substrate 11, a giant magneto-resistive effect layer 17 is formed that includes a lower ferromagnetic material layer 14a, a first Heusler alloy insertion layer (lower Heusler alloy layer) 14b, a second non-magnetic material layer 15, a second Heusler alloy insertion layer (upper Heusler alloy layer) 16b, and an upper ferromagnetic material layer 16a in this order (S102). In this step, the first Heusler alloy insertion layer 14b and the second Heusler alloy insertion layer 16b preferably each have a thickness of 1.0 nm or more and less than 7 nm. The lower ferromagnetic material layer 14a and the upper ferromagnetic material layer 16a preferably each have a thickness of 0.2 nm to 7 nm. One or a plurality of multilayers of the giant magneto-resistive effect layer 17 may be provided. Next, cap layers 18a and 18b are formed on the giant magneto-resistive effect layer 17 formed on the silicon substrate. Finally, the silicon substrate with the giant magneto-resistive effect layer 17 and the cap layers 18a and 18b formed is subjected to a heat treatment as post-annealing at 0° C. or more and 1000° C. or less (S104). The post annealing may be performed in a film forming device before forming the cap layers 18a and 18b. The heat treatment temperature is preferably 200° C. or more and 600° C. or less.

Next, details of the step of forming a giant magneto-resistive effect layer will be described with reference to FIG. 2(B). In the step of forming a giant magneto-resistive effect layer 17, first, a lower ferromagnetic material layer 14 is formed (S122). Next, a first Heusler alloy insertion layer (lower Heusler alloy layer) 14b is formed (S124). Then, a second non-ferromagnetic material layer 15 is formed (S126). Subsequently, a second Heusler alloy insertion layer (upper Heusler alloy layer) 16b is formed (S128). Finally, an upper ferromagnetic material layer 16 is formed (S130). In this way, formation of a film of the giant magneto-resistive effect layer 17 as a multilayer is completed. In a case where a plurality of giant magneto-resistive effect layers 17 are provided, the process of FIG. 2(B) is to be appropriately repeated.

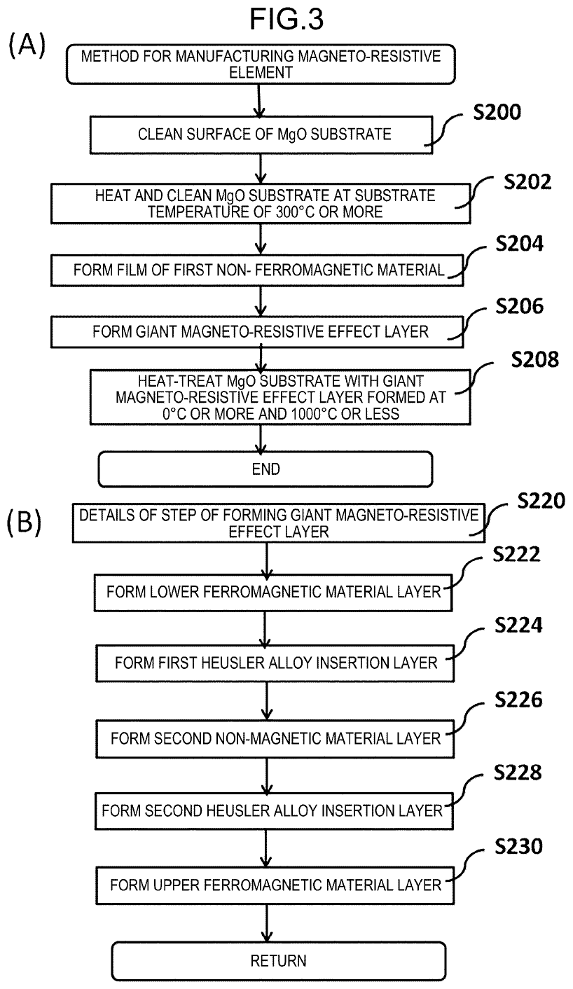

FIG. 3 shows flowcharts illustrating a method for manufacturing a magneto-resistive element including a giant magneto-resistive effect layer, using a MgO substrate, and showing a second embodiment of the present invention, and (A) is a whole schematic process diagram, and (B) is a detailed diagram of a step of forming a giant magneto-resistive effect layer. In FIG. 3(A), first, the surface of a MgO substrate is cleaned (S200). Next, the MgO substrate is heated and cleaned at a substrate temperature of 300° C. or more (S202). Then, on the MgO substrate heated and cleaned, a film of a first non-ferromagnetic material is formed at a substrate temperature of 0° C. or more and 1000° C. or less (S204).

Next, on the film of the first non-magnetic material formed on the MgO substrate, a giant magneto-resistive effect layer 17 is formed that includes a lower ferromagnetic material layer 14a, a first Heusler alloy insertion layer 14b (lower Heusler alloy layer), a second non-magnetic material layer 15, a second Heusler alloy insertion layer (upper Heusler alloy layer) 16b, and an upper ferromagnetic material layer 16a in this order (S206). In this step, the first Heusler alloy insertion layer 14b and the second Heusler alloy insertion layer 16b preferably each have a thickness of 1.0 nm or more and less than 7 nm. The lower ferromagnetic material layer 14a and the upper ferromagnetic material layer 16a preferably each have a thickness of 0.2 nm to 7 nm. One or a plurality of multilayers of the giant magneto-resistive effect layer 17 may be provided. Next, cap layers 18a and 18b are formed on the giant magneto-resistive effect layer 17 formed on the MgO substrate. Finally, the MgO substrate with the giant magneto-resistive effect layer 17 and the cap layers 18a and 18b formed is subjected to a heat treatment as post-annealing at 0° C. or more and 1000° C. or less (S208). The heat treatment temperature is preferably 200° C. or more and 600° C. or less.

Next, details of the step of forming a giant magneto-resistive effect layer will be described with reference to FIG. 3(B). In the step of forming a giant magneto-resistive effect layer 17, first, a lower ferromagnetic material layer 14 is formed (S222). Next, a first Heusler alloy insertion layer (lower Heusler alloy layer) 14b is formed (S224). Then, a second non-ferromagnetic material layer 15 is formed (S226). Subsequently, a second Heusler alloy insertion layer (upper Heusler alloy layer) 16b is formed (S228). Finally, an upper ferromagnetic material layer 16 is formed (S230). In this way, formation of a film of the giant magneto-resistive effect layer 17 as a multilayer is completed. In a case where a plurality of giant magneto-resistive effect layers 17 are provided, the process of FIG. 3(B) is to be appropriately repeated.

Next, the present invention will be described in detail by using specific Examples, but it should be noted that the present invention is not limited to these Examples.

### EXAMPLES

As an example, results are shown below in which the MR ratio and ARA are improved in the case of producing and measuring a CPP-GMR element having a Co₅₀Fe₅₀/Co₂(Fe_{0.4}Mn_{0.6})Si/Ag/Co₂(Fe_{0.4}Mn_{0.6})Si/Co₅₀Fe₅₀ epitaxial multilayered structure as compared with the case of a CPP-GMR element having a Co₂(Fe_{0.4}Mn_{0.6})Si/Ag/Co₂(Fe_{0.4}Mn_{0.6})Si epitaxial multilayered structure not having a ferromagnetic layer/Heusler alloy layer interface. Hereinafter, Co₅₀Fe₅₀ is referred to as CF, and Co₂(Fe_{0.4}Mn_{0.6})Si is referred to as CFMS.

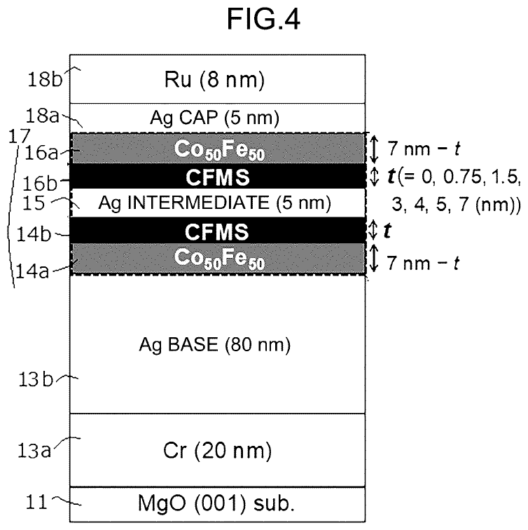

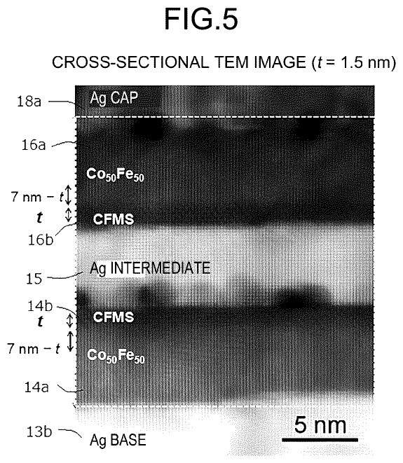

FIG. 4 shows the produced multilayered structure. Specifically, the produced multilayered structure is a MgO(001) substrate/Cr (20 nm)/a Ag base layer (80 nm)/CF (7-t nm)/CFMS (t nm)/Ag intermediate layer (5 nm)/CFMS (t nm)/CF (7-t nm)/a Ag cap layer (5 nm)/Ru (8 nm), and is a single-crystal multilayered film with a (001) orientation. Structures were produced that included a CFMS layer having a thickness t of 0 (without a CFMS layer), 0.75, 1.5, 3, 4, 5, and 7 (without a CF layer) (nm), respectively. After deposition of the Ag base layer, a heat treatment was performed at 300° C. for 30 minutes, and a heat treatment was performed at 450° C. for 2 minutes after deposition of each CF layer for a sample of t=0 nm, and after deposition of each CFMS layer for the other samples. From the transmission electron microscope image (TEM) shown in FIG. 5, formation of an epitaxial multilayered structure was confirmed without atomic diffusion into the Ag intermediate layer and remarkable unevenness of the layer interface.

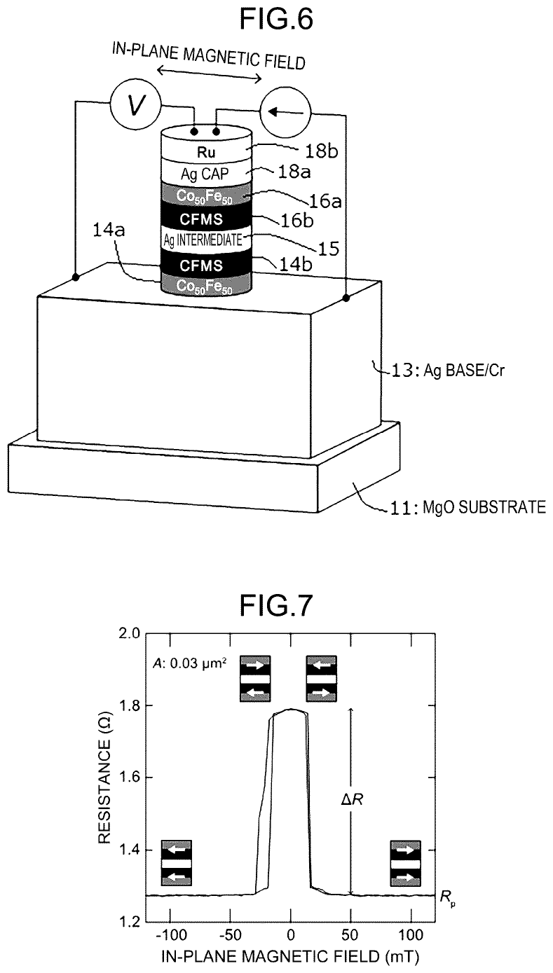

FIG. 6 is a schematic view of a CPP-GMR element. The multilayered structure in FIG. 4 was micromachined into a pillar shape having a size of submicron order. A magnetic field was applied in an in-plane direction of the pillar, and resistance change was measured in a DC four-terminal arrangement. FIG. 7 shows a representative MR curve observed at room temperature for a CPP-GMR element of t=4 nm. The pillar size is about 0.03 μm². The resistance of the pillar changes between the time when the magnetization arrangement is parallel and the time when the magnetization arrangement is antiparallel. The amount of resistance change is represented by ΔR, and the resistance value in the parallel arrangement is represented by Rₚ.

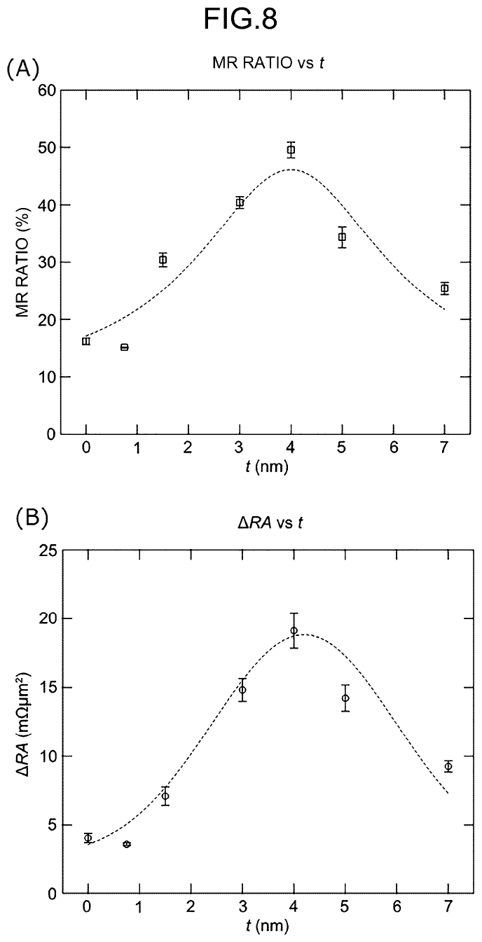

FIGS. 8(A) and 8(B) show the averaged dependency of MR ratio and ARA on t. The MR ratio is determined by measuring an MR curve as shown in FIG. 7 for a large number of pillars having various sizes to extract ΔR from each MR curve observed and obtain a slope of ΔR to Rₚ as an MR ratio. ΔRA is estimated by multiplying the MR ratio by the averaged value of Rₚ× A. It can be seen that in the structures of t=3, 4, and 5 nm, the MR ratio and ARA are clearly improved as compared with the structure of t=7 nm (CFMS/Ag/CFMS multilayered structure). In particular, in the case of t=4 nm, the MR ratio is 49% and ARA is 19 mΩμm², and the MR ratio and ARA are significantly improved as compared with the case of t=7 nm (25%, 9 mΩμm²).

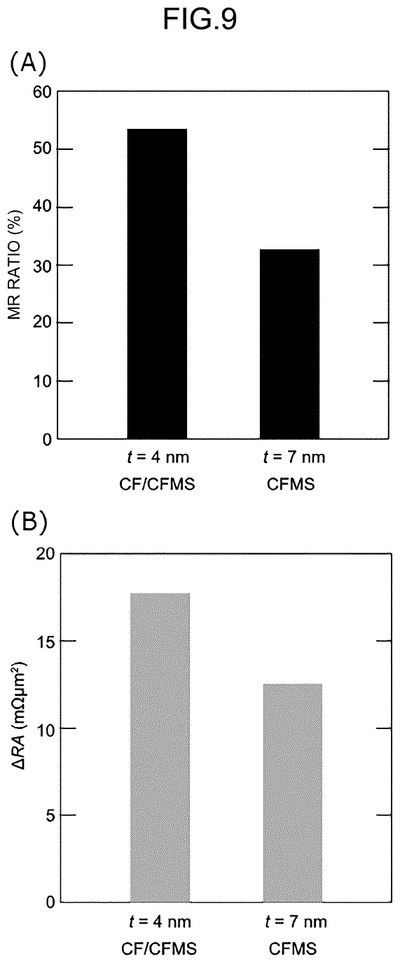

FIGS. 9(A) and 9(B) are graphs showing the MR ratio and ARA at t=4 nm and t=7 nm calculated based on the theory regarding the spin-dependent transport in a CPP-GMR element [T. Valet and A. Fert, Phys. Rev. B 48, 7099 (1993), N. Strelkov et al., J. Appl. Phys. 94, 3278 (2003)]. As γ at the CF/CFMS interface, a value obtained by theoretical calculation of band matching (0.97) is used. The calculation results also show that both the MR ratio and ARA are clearly improved at t=4 nm.

From the above results, it has been demonstrated that the ferromagnetic/Heusler alloy/non-magnetic/Heusler alloy/ferromagnetic multilayered structure is effective for improving the MR ratio and ΔRA, that is, improving the performance of the CPP-GMR element, and that for exhibiting the function, the film thickness can be controlled in the order of nanometers.

In an embodiment of the present invention, a case of producing a single-crystal CPP-GMR element is mainly described, but the present invention is not limited thereto, and the same effect can be obtained not only in the case of a single-crystal CPP-GMR element but also in the case of a polycrystalline CPP-GMR element. Furthermore, a case is shown in which an Ag layer is used as a non-magnetic intermediate layer of a CPP-GMR element, but the present invention is not limited thereto, and as described above, a non-magnetic metal layer such as a general-purpose Cu layer or Al layer may be used.

### INDUSTRIAL APPLICABILITY

The magneto-resistive element of the present invention is a giant magneto-resistive element using a Heusler alloy having good magnetoresistance characteristics required for application to an actual device such as a reading head of a magnetic hard disk, and is suitably used in a practical device such as a magnetic head, a magnetic field sensor, a spin electronic circuit, or a tunnel magnetoresistance device.

### REFERENCE SIGNS LIST

11 Silicon substrate, MgO substrate
12 Base layer
13, 13a, 13b First non-magnetic layer (lower electrode layer)
14a Lower ferromagnetic layer
14b Heusler alloy insertion layer (lower Heusler alloy layer)
16b Second non-magnetic layer
16b Heusler alloy insertion layer (upper Heusler alloy layer)
16a Upper ferromagnetic layer
17 Giant magneto-resistive effect layer
18a, 18bCap layer

1. A current-perpendicular-to-plane giant magneto-resistive element comprising:
a substrate composed of a silicon substrate;
a base layer layered on the substrate;
a first non-magnetic layer layered on the base layer; and
a giant magneto-resistive effect layer including at least one multilayer including a lower ferromagnetic layer, a lower Heusler alloy layer, a second non-magnetic layer, an upper Heusler alloy layer, and an upper ferromagnetic layer.

2. The current-perpendicular-to-plane giant magneto-resistive element according to claim 1, wherein the silicon substrate is a Si(001) single-crystal substrate.

3. The current-perpendicular-to-plane giant magneto-resistive element according to claim 1, wherein the base layer is composed of at least one selected from the group consisting of Cr, Fe, and CoFe.

4. The current-perpendicular-to-plane giant magneto-resistive element according to claim 1, wherein the base layer has a thickness of 10 nm or more and less than 200 nm.

5. A current-perpendicular-to-plane giant magneto-resistive element comprising:
a substrate composed of a MgO substrate;
a first non-magnetic layer layered on the substrate; and
a giant magneto-resistive effect layer including at least one multilayer including a lower ferromagnetic layer, a lower Heusler alloy layer, a second non-magnetic layer, an upper Heusler alloy layer, and an upper ferromagnetic layer.

6. The current-perpendicular-to-plane giant magneto-resistive element according to claim 5, wherein the MgO substrate is a (001) single-crystal substrate.

7. The current-perpendicular-to-plane giant magneto-resistive element according to claim 1, wherein
the first non-magnetic layer is at least one selected from the group consisting of Ag, V, Cr, W, Mo, Au, Pt, Pd, Ta, Ru, Re, Rh, NiO, CoO, TiN, and CuN,
the lower ferromagnetic layer is composed of Fe, Co, Ni, or a binary or ternary alloy of Fe, Co, and Ni,
the lower Heusler alloy layer is a Co-based Heusler alloy,
the second non-magnetic layer is composed of at least one selected from the group consisting of Ag, Cu, Al, AgZn, and AgSn,
the upper Heusler alloy layer is a Co-based Heusler alloy, and
the upper ferromagnetic layer is composed of Fe, Co, Ni, or a binary or ternary alloy of Fe, Co, and Ni.

8. The current-perpendicular-to-plane giant magneto-resistive element according to claim 7, wherein
the Co-based Heusler alloy has a formula of Co₂YZ wherein
Y is composed of at least one selected from the group consisting of Ti, V, Cr, Mn, and Fe and Z is composed of at least one selected from the group consisting of Al, Si, Ga, Ge, In, and Sn.

9. The current-perpendicular-to-plane giant magneto-resistive element according to claim 1, wherein
the first non-magnetic layer has a thickness of 0.5 nm or more and less than 100 nm,
the lower ferromagnetic layer has a thickness of 0.2 nm or more and less than 7 nm,
the lower Heusler alloy layer has a thickness of 1.0 nm or more and less than 7 nm,
the second non-magnetic layer has a thickness of 1 nm or more and less than 20 nm,
the upper Heusler alloy layer has a thickness of 1.0 nm or more and less than 7 nm,
the upper ferromagnetic layer has a thickness of 0.2 nm or more and less than 7 nm,
a total thickness of the lower ferromagnetic layer and the lower Heusler alloy layer is 1.2 nm or more and less than 14 nm, and
a total thickness of the upper ferromagnetic layer and the upper Heusler alloy layer is 1.2 nm or more and less than 14 nm.

10. The current-perpendicular-to-plane giant magneto-resistive element according to claim 1, having
a magnetoresistance ratio of 20% or more and
a resistance change-area product (ARA) of 7 mΩμm² or more.

11. The current-perpendicular-to-plane giant magneto-resistive element according to claim 1, wherein the giant magneto-resistive effect layer has a single-crystal structure having an epitaxial crystal orientation of a (001), (110), or (211) orientation as a crystal orientation indicated by a Miller index.

12. The current-perpendicular-to-plane giant magneto-resistive element according to claim 1, wherein the giant magneto-resistive effect layer has a polycrystalline structure.

13. A device comprising the current-perpendicular-to-plane giant magneto-resistive element according to claim 1.

14. The device according to claim 13, being a readout head to be used in a storage element, a magnetic field sensor, a spin electronic circuit, or a tunnel magnetoresistance (TMR) device.

15. A method for manufacturing a current-perpendicular-to-plane single-crystal giant magneto-resistive element, the method comprising:
a step of preparing a silicon substrate;
a step of forming a single-crystal base layer on the silicon substrate;
a step of forming a film of a first non-ferromagnetic material at a substrate temperature of 0° C. or more and 1000° C. or less on the single-crystal base layer formed on the silicon substrate;
a step of forming, on the film of the first non-ferromagnetic material formed on the single-crystal base layer, a giant magneto-resistive effect layer including at least one multilayer including a lower ferromagnetic material layer, a lower Heusler alloy layer, a second non-ferromagnetic material layer, an upper Heusler alloy layer, and an upper ferromagnetic material layer; and
a step of heat-treating the silicon substrate, with the giant magneto-resistive effect layer formed, at 0° C. or more and 1000° C. or less.

16. A method for manufacturing a current-perpendicular-to-plane single-crystal giant magneto-resistive element, the method comprising:
a step of preparing a MgO substrate;
a step of forming a film of a first non-ferromagnetic material at a substrate temperature of 0° C. or more and 1000° C. or less on the MgO substrate;
a step of forming, on the film of the first non-ferromagnetic material formed on the MgO substrate, a giant magneto-resistive effect layer including at least one multilayer including a lower ferromagnetic material layer, a lower Heusler alloy layer, a second non-ferromagnetic material layer, an upper Heusler alloy layer, and an upper ferromagnetic material layer; and
a step of heat-treating the MgO substrate, with the giant magneto-resistive effect layer formed, at 0° C. or more and 1000° C. or less.

17. A method for manufacturing a current-perpendicular-to-plane polycrystalline giant magneto-resistive element, the method comprising:
a step of preparing a substrate of silicon, glass, alumina, germanium, gallium arsenide, yttria-stabilized zirconia, or AlTiC;
a step of forming a base layer that serves as a polycrystalline electrode on the substrate;
a step of forming a film of a first non-ferromagnetic material on the base layer formed on the substrate;
a step of forming, on the film of the first non-ferromagnetic material formed on the base layer, a giant magneto-resistive effect layer including at least one multilayer including a lower ferromagnetic material layer, a lower Heusler alloy layer, a second non-ferromagnetic material layer, an upper Heusler alloy layer, and an upper ferromagnetic material layer; and
a step of heat-treating the substrate, with the giant magneto-resistive effect layer formed, at 0° C. or more and 500° C. or less.
